(19) United States
(12) Patent Application Publication
(10) Pub. No.: US 2022/0373898 A1
(43) Pub. Date: Nov. 24, 2022

(54) MICRO-OPTIC CELL DESIGN RANDOMLY POSITIONED LENSLETS AND STATISTICAL RECONSTRUCTION OF A MICRO-LENS ARRAY

(71) Applicant: Luminit LLC, Torrance, CA (US)

(72) Inventors: Alex I. Martin, Torrance, CA (US); Riberet Almeida, Torrance, CA (US); Casey Irvin, Torrance, CA (US); Anthony Ang, Torrance, CA (US)

(21) Appl. No.: 17/880,217

(22) Filed: Aug. 3, 2022

Related U.S. Application Data
(63) Continuation of application No. 16/778,820, filed on Jan. 31, 2020.
(60) Provisional application No. 62/800,230, filed on Feb. 1, 2019.

(51) Int. Cl. G03F 7/20; H01L 27/146; G02B 3/00

(52) U.S. Cl. CPC G03F 7/70833; H01L 27/146; G02B 3/0062; G03F 7/0012

(57) ABSTRACT

A micro-optic cell design with randomly positioned lenslets is provided herein that uses statistical reconstruction of a micro-lens array. A method of making an optical element, which includes a micro-optic unit cell comprising one or more lenslets, is also disclosed.

### CROSS-REFERENCE TO RELATED APPLICATIONS

This application is a continuation of U.S. patent application Ser. No. 16/778,820, filed Jan. 31, 2020, which claims the benefit of priority of pending U.S. Provisional Patent Application Ser. No. 62/800,230, filed Feb. 1, 2019, the entire disclosure of which is hereby incorporated herein by reference.

### BACKGROUND

The formation of a regular, repeated micro-lens array (MLA) creates diffracted orders related to the repeated pitch across the transverse and longitudinal axes of the structured surface plane when using coherent light. Forming a homogenized image expected from a single lenslet is needed for creating outputs, such as flat tops/top hats, which the present application addresses.

### SUMMARY

Provided herein is an optical element that includes a micro-optic unit cell comprising one or more lenslets. In one embodiment, the lenslets are randomly positioned. In another embodiment, the optical element can include a flat top. Another embodiment includes the optical element having a coherent light source or an incoherent light source.

In another embodiment, the boundary shape of the lenslet comprises a square, a rectangle, a circle, an ellipse, a hexagon, a star, a cross, a logo, a generic geometrical shape with enclosed boundary(ies), or a mixture thereof, where the boundary shapes are not necessarily centered around the specular projection. Also, in an alternative embodiment, the intensity or irradiance profile comprises a flat top, a gradient, or mixtures thereof. The lenslets are random and statistically uniformly distributed within the micro-optic unit cell in another embodiment.

In one embodiment, in order to fill the entire unit cell area, the lenslets, which are randomly algorithmically placed at a later time, overwrite the area of any previous pattern of lenslets. In another embodiment, the unit cell is filled with the lenslets so that there are no blank areas, which could cause a coherent diffractive zero order or incoherent specular light in a diffuser. In a different embodiment, where the intension is to have zero order or specular light, where the unit cell does not have to be filled 100% by the lenslets.

In a different embodiment, the size of the micro-optic unit cell is based on lenslet size, beam size or source size, and shape of the optical element. Also, the lenslets can wrap around one or more edges of the micro-optic unit cell. Optionally, the lenslet comprises a size of about 20-500 micrometers. In another embodiment, the micro-optic unit cell comprises a size in the range of about 0.5-4 millimeters. In still another embodiment, the micro-lens array comprises a size of about 3 millimeters to about 6 inches having repeated micro-optic unit cells.

In a different embodiment, the parts which result from the masters are optical in nature, where some portion of the electromagnetic (EM) spectrum is propagated onto and through for refractive results of the desired intensity or irradiance profiles. The parts can also be used in reflective mode where the desired intensity or irradiance profiles are designed. In addition, a mixture of the refracted and reflected components of EM spectrum are used in combination. Also, the materials have corresponding optical properties appropriate to the effect desired by the user. The materials for the parts can be made of any solid composition, which has optical properties, such as plastics, UV cured epoxies, resins, glass, crystals, metals, coated surfaces, and the like.

Another embodiment is a method of making an optical element comprising a micro-optic unit cell comprising one or more lenslets comprising a rubber master, glass master, metal master, plastic master or any solid material, which can be formed for replication. The method can include a photolithography process or the use of a direct write laser machine.

The micro-optic cell with randomly positioned lenslets described herein has several benefits and advantages. One particular benefit is that the final format of the design is robust and repeatable to different boundary shapes of lenslet designs (square, rectangular, circular, elliptical, hexagons, logo, a generic geometrical shape with enclosed boundary(ies) etc., which do not have to be centered about the specular ray) and different intensity or irradiance profiles of a lenslet (top hat/flat top, gradient, etc.). The randomness along the edge of the micro-optic cell allows a small formatted area to be seamlessly repeated to a large format, which is beneficial for flat panels and round drums used in embossing large volumes of optical components. Also, another benefit is that no diffraction orders are present in the final image. Yet another benefit is that coherent and incoherent light can be used as the projected source.

### BRIEF DESCRIPTION OF THE DRAWINGS

The patent or application file contains at least one drawing executed in color. Copies of this patent or patent application publication with color drawings will be provided by the Office upon request and payment of the necessary fee.

FIG. 1. Functional method of construction, single lens element. This case is of an anamorphic lens design with a square aperture.

FIG. 2. Functional method of construction, single lens element having randomly placed lenslets per unit cell.

FIG. 3. Functional method of construction, single lens element for a 30×30 MLA where each pixel is found 900 times within the unit cell.

FIG. 4. Functional method of construction, single lens element where statistics and error calculations are made.

FIG. 5. Functional method of construction for a single lens element showing the frequency of distribution related to each pixel found in the array and the cumulative errors in one step of the process.

FIG. 6. Functional method of construction, single lens element and normalizing the cumulative errors within the lenslet to 8-bit grayscale values for the average error of a single lenslet.

FIG. 7. Functional method of construction, single lens element showing the reconstructed lenslet.

FIG. 8. Functional method of construction, single lens element showing reconstruction of errors across the unit cell using the indexed position of each pixel.

FIG. 9. Functional method of construction, single lens element with pre-compensation of the unit cell design for cumulative errors then normalization back into 8-bit greyscale image.

FIG. 10. Functional method of construction, single lens element showing less than 1% design errors.

FIG. 11. Functional method of construction, single lens element which can use a direct laser write machine, an example of which is pictured.

FIG. 12. Functional method of construction, single lens element where statistical reconstruction and repositioning leads to no diffraction effects in the image.

FIG. 13. Simulation of Flat Top Diffuser 20 degrees by 20 degrees (FTD20×20) micro structure with regular repeated Micro Lens Array (MLA).

FIG. 14. Simulation of the FTD20×20 pattern from a regular repeated MLA of square pattern.

FIG. 15. Simulation of FTD20×20 micro structure with randomly positioned lenslets.

FIG. 16. Simulation of the FTD20×20 far field pattern from randomly positioned lenslets.

FIG. 17. Simulation of FTD10×10 micro structure with regular repeated MLA.

FIG. 18. Simulation of the FTD10×10 far field pattern from a MLA.

FIG. 19. Simulation of FTD10×10 micro structure with randomly positioned lenslets.

FIG. 20. Simulation of the FTD10×10 far field pattern from randomly positioned lenslets.

FIG. 21. Simulation of FTD20×10 micro structure with regular repeated MLA.

FIG. 22. Simulation of the FTD20×10 far field pattern from a regular repeated MLA.

FIG. 23. Simulation of FTD20×10 micro structure with randomly positioned lenslets.

FIG. 24. Simulation of the FTD20×10 far field pattern from randomly positioned lenslets.

FIG. 25. Simulation of Elliptical FTD20×10 micro structure with regular repeated MLA.

FIG. 26. Simulation of the FTD20×10 far field pattern from a MLA.

FIG. 27. Simulation of Elliptical FTD20×10 micro structure with randomly positioned lenslets.

FIG. 28. Simulation of the Elliptical FTD20×10 far field pattern from randomly positioned lenslets.

FIG. 29. Confocal (3D) microscope measurement of a regularly spaced MLA.

FIG. 30. Photograph of far field irradiance distribution of a regularly spaced MLA.

FIG. 31. Confocal microscope measurement of randomly located lenslets.

FIG. 32. Confocal microscope measurement of randomly located lenslets.

FIG. 33. Confocal microscope measurement of randomly located lenslets.

FIG. 34. Confocal microscope measurement of randomly located lenslets.

FIG. 35. Photograph of far field irradiance distribution of a randomly placed lenslets.

### DETAILED DESCRIPTION

Provided herein is an optical element that includes a micro-optic unit cell made of one or more lenslets. A micro-optic unit cell is a single unit of composed of several lenslets. The size of the micro-optic unit cell is based on lenslet size, beam aperture, beam size, source size, and shape of the optical element and are in the range of about 0.5-4 millimeters. The lenslet is a single lens element having a size of about 20-500 micrometers. A micro-lens array (MLA) is an optical element has a size of about 3 millimeters to about 6 inches and is composed of repeated micro-optic unit cells. The shape of the lenslet can be almost any known geometric shape, such as a square, a rectangle, a circle, an ellipse, a hexagon, a star, a cross, a donut, a logo, a generic geometrical shape with enclosed boundary(ies) or mixtures thereof, where the boundary shapes are not necessarily centered around the specular projection. The lenslets can be uniformly distributed within the micro-optic unit cell or can be randomly positioned. The lenslets wrap around one or more edges of the micro-optic unit cell. Initially, the lenslets have the same size and shape.

In yet another embodiment, the lenslets also have the same orientation (not rotated) with respect to each other. In still another embodiment, the lenslets are random and statistically uniformly distributed within the micro-optic unit cell.

In order to fill the entire unit cell area, the lenslets, which are randomly algorithmically placed at a later time, overwrite the area of any previous pattern of lenslets. In one embodiment, the unit cell is filled with the lenslets so that there are no blank areas, which could cause a coherent diffractive zero order or incoherent specular light in a diffuser. In a different embodiment, where the intension is to have zero order or specular light, wherein the unit cell does not have to be filled 100% by the lenslets.

The intensity or irradiance profile of the MLA or micro-optic unit cell can be a flat top, a gradient, or mixtures thereof. The optical element can be a flat top. A flat-top/top-hat is a homogenized, projected image having uniform intensity. The optical element can have a coherent light source or an incoherent light source.

The method of making the optical element involves making a micro-optic cell of some size, XY, filled with lenslets of some size m×n. Each lenslet with sag(Z) is placed in a random position across X and Y independently. This writing process is iterated in the framework of the cell design until all blank areas are overwritten with the form of the lenslet. In a case that a new lenslet is randomly positioned in an area previously filled with a portion of another lenslet, the area is overwritten with the new lenslet. The result is a full lens overlapping a partial lens. The writing process is repeated and formed randomly, and this case may occur several times during the design of the micro-optic cell. If the cell is large enough, then the cell should have a statistical distribution of sag(Z) holding the same as that of a single lenslet. When the micro-optic cell design is large enough, then the cell can be repeated to a larger formatted area without diffraction effects from a coherent light source.

Also included herein is a method of making an optical element that uses a micro-optic unit cell made of one or more lenslets from a rubber master or a plastic master for replication. The method includes a photolithography process, which can be done with a direct write laser machine.

In a different embodiment, the parts which result from the masters are optical in nature, where some portion of the electromagnetic (EM) spectrum is propagated onto and through for refractive results of the desired intensity or irradiance profiles. The parts can also be used in reflective mode where the desired intensity or irradiance profiles are designed. In addition, a mixture of the refracted and reflected components of EM spectrum are used in combination. Also, the materials which are used have corresponding optical properties appropriate to the effect desired by the user of the parts. The materials for the parts can be made of any solid which have optical properties, such as plastics, UV cured epoxies, resins, glass, crystals, metals, coated surfaces, and the like.

The method of construction of the micro-optic cell is as follows:

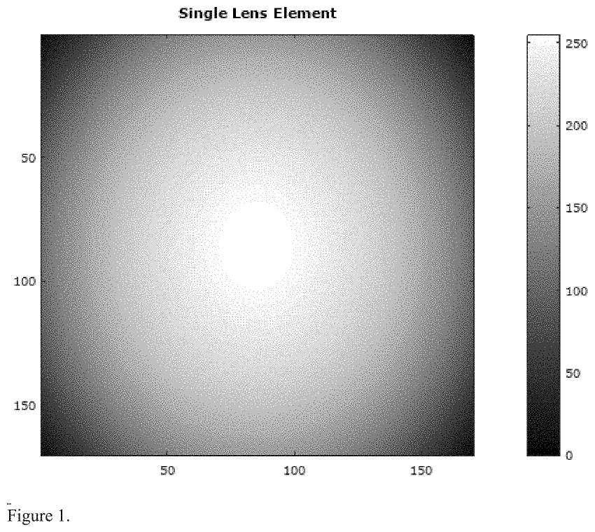

Input: Lenslet design is formed. Lenslet could be any shape (square, rectangular, circular, ellipse, hexagon, star, cross, masked logo, a generic geometrical shape with enclosed boundary(ies) or mixtures thereof). The expected output is beam homogenizer or corrector or image projection to any shape, according to FIG. 1.

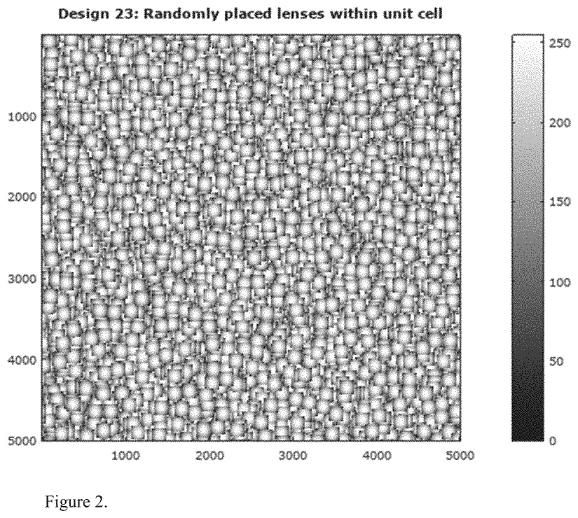

Each lens is positioned across the specified XY dimensions of the unit cell with statistically uniform random distribution positions of the lenslet to a unit cell. The lenslets all have identical size, shape (initially) and orientation. The size of the unit cell is predetermined based on the size of the lenslet, the aperture of the beam, and the design of the optical part. The first process of randomization is based on statistical uniform distribution functions of the full area of the unit cell. The second process of randomization is correcting the statistical uniform distribution functions to infill deformed areas with the unit cell. In this process, previously written lenses may be overwritten several times by other lenslets positioned in the unit cell. Also, lenses wrap around the edge from right to left or bottom to top. This applies to continuous MLA design in the end, according to FIG. 2.

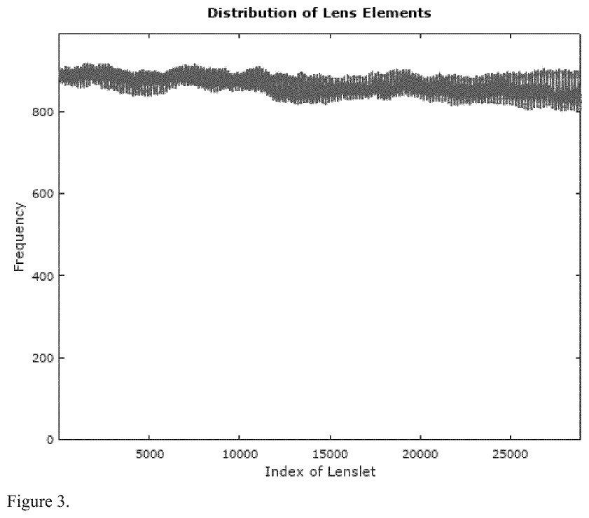

Every design pixel of the lenslet is assigned an index. Running a parallel process of reconstructing the unit cell with index values, instead of sag(Z) values, allows for the formation and analysis of the frequency distribution of each pixel of the original lenslet found within the unit cell. For example, in an example of an expected 30×30 MLA, each pixel is found 900 times within the unit cell. The same is to be expected within the randomized unit cell because of the reconstruction method, according to FIG. 3.

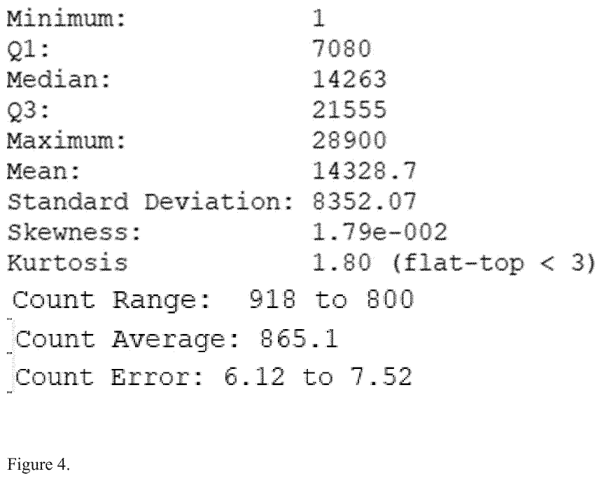

Additional statistics and error calculations are made to determine how well the current unit cell will reconstruct the function of the lenslet. In one embodiment, a flat-top distribution is considered as a kurtosis value less than 3. In another embodiment, skewness is about 0 and the upper and lower bounds of error are less than 10 percent, according to FIG. 4.

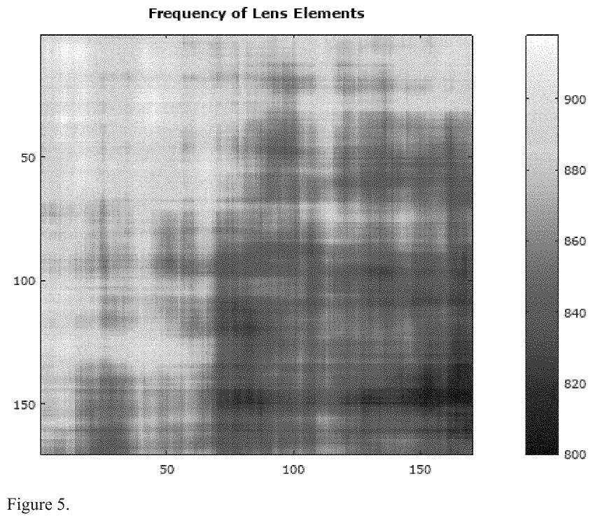

The frequency distribution related to each pixel found in the array in the format of the lenslet are analyzed and show the cumulative errors of the unit cell in this state of the design process, according to FIG. 5.

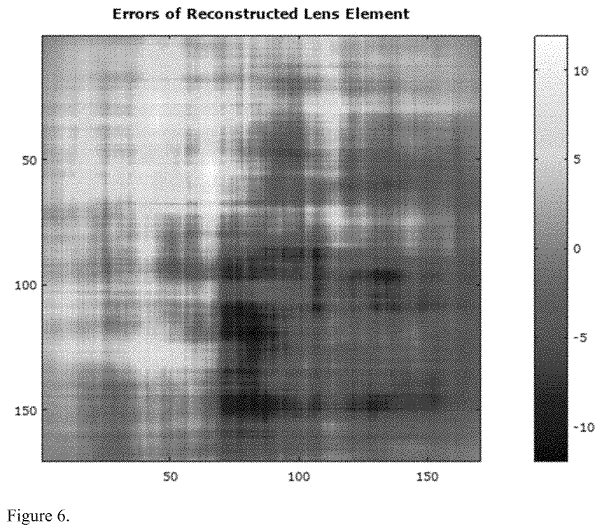

The cumulative errors are normalized within the lenslet to 8-bit grayscale values for the average error of a single lenslet, according to FIG. 6.

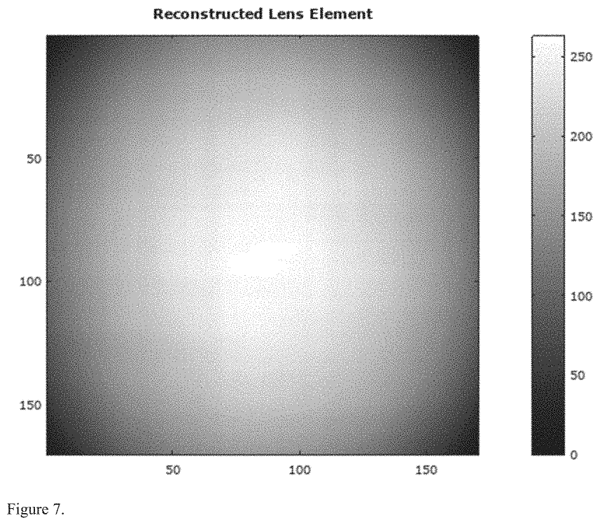

The features of a lenslet with average errors are reconstructed, showing that the lenslet is a convolution of the original lenslet design and the errors of repeated randomization and reconstruction, according to FIG. 7.

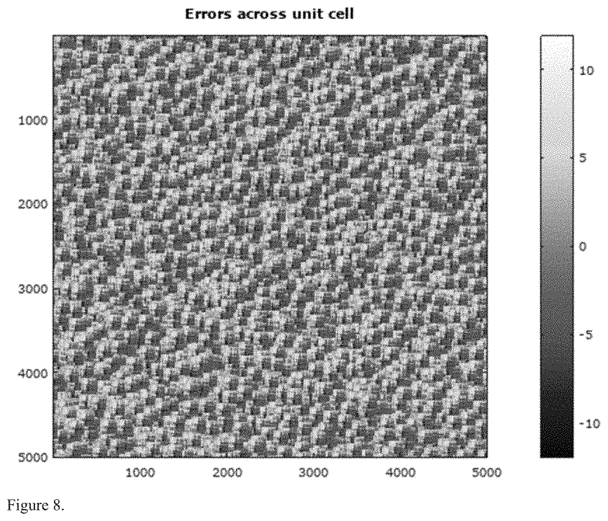

These errors are reconstructed across the unit cell using the indexed position of each pixel, according to FIG. 8.

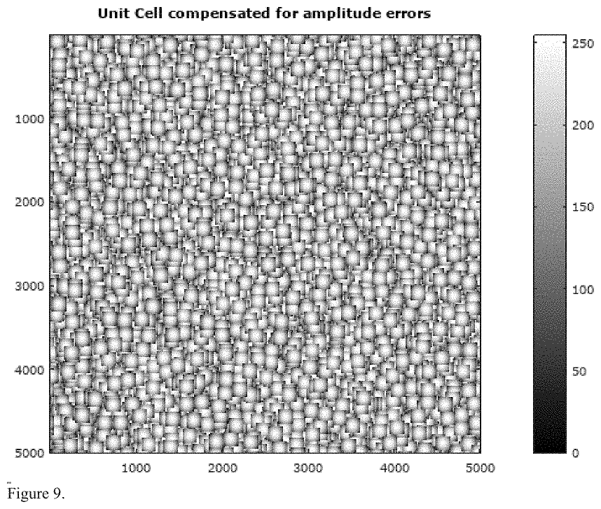

The unit cell design is pre-compensated for these cumulative errors, then normalized back into an 8-bit greyscale image, according to FIG. 9.

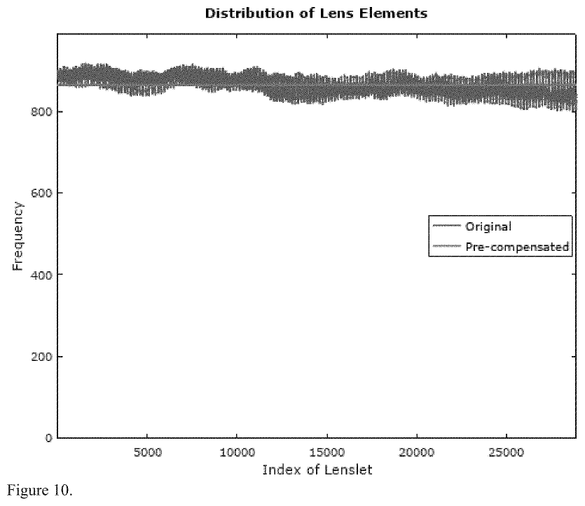

This reconstruction ensures that the unit cell design has minimal errors, depending on the size of the element and number of repetitions within the unit cell. In one embodiment, the design errors cumulate to <1%, according to FIG. 10.

The assigned 8-bit grey values are converted to depth values and are written as a negative profile within a photolithography process using the direct laser write (DWL) machine, according to FIG. 11. The manufacturing process includes a rubber master, a plastic master, a metal master, or any other solid material for part replication where the parts are rubber, a plastic, a metal, or any other solid material.

Micro lens arrays (MLA's) are fabricated using either a Direct-Write-Laser (DWL) technique that is capable of exposing grayscale or with the use of grayscale Photomasks. In the former technique, the lenslets, which are represented as grayscale bitmaps and are indicative of the varying depths spatially, are imaged into photoresist. The other photolithography techniques which uses dithered photomasks can also be used to produce these microlenses in photoresist. The photoresist of choice is a low contrast photoresist that is suitable for grayscale imaging where variable exposure intensities are used to control the depths at every “pixel” of the design. While DWL techniques make use of a rastering laser beam that is acoustically modulated via an acousto-optic modulator (AOM) to control the intensity of the rastering laser beam, a Photomask aligner or a stepper/scanner makes use of reduction lenses to expose these structures in resist. The photoresists are then developed in a developer bath, which results in the shapes of the microlenses. The exposure dose and/or development time in both the above lithography techniques are used to control the final depths or sags of the microlenses. The Peak-to-Valley (PV) depths/heights are theoretically calculated beforehand to achieve the right exposure conditions. The structures in photoresist are then replicated into transparent thermal or UV curable polymers. The refractive index of the replicating material/polymer is taken into consideration while designing the optical elements.

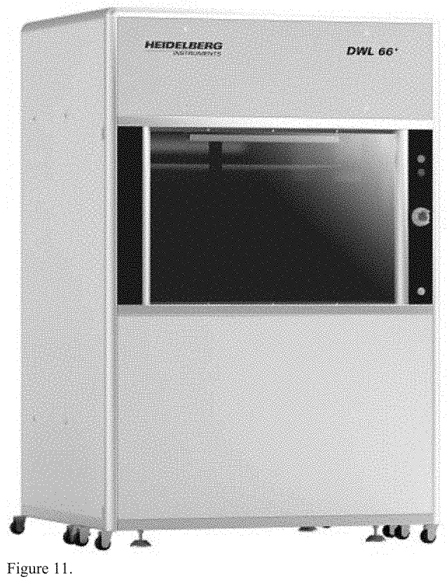

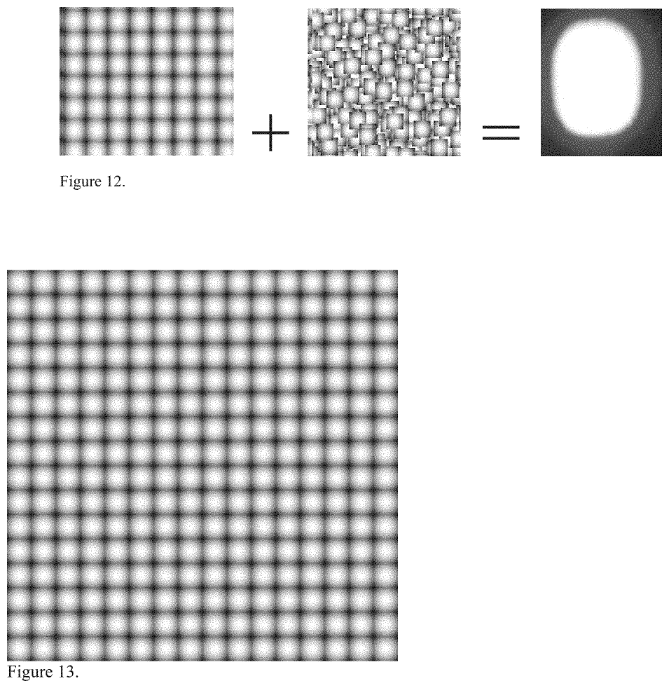

Even with some computational errors, the unit cell functions similar to the expected function of a regular repeated MLA. The main advantage is that this randomized MLA has no diffraction effects in the image, according to FIG. 12.

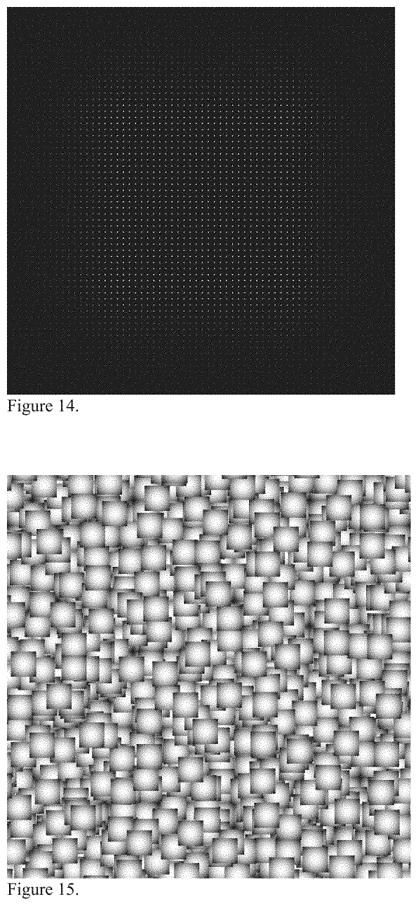

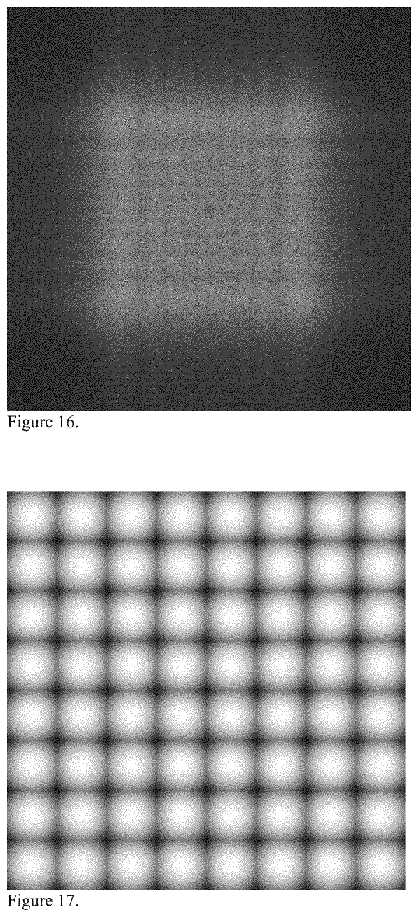

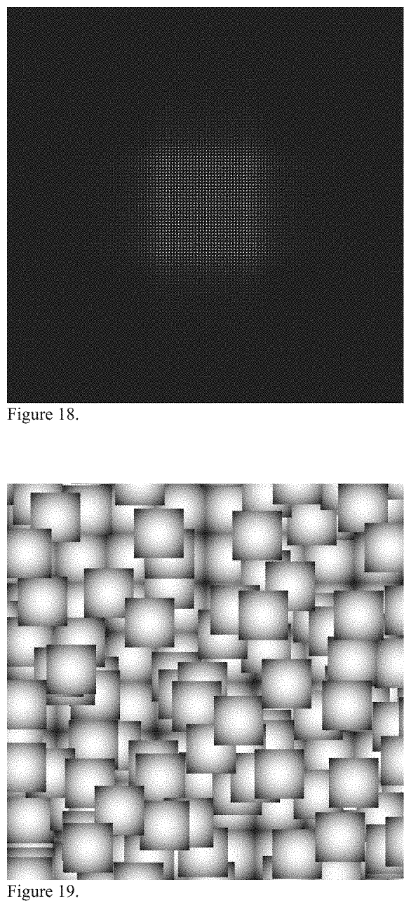

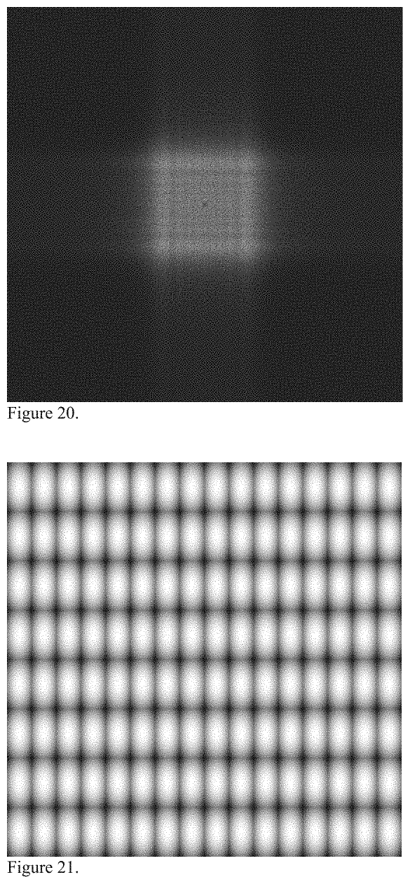

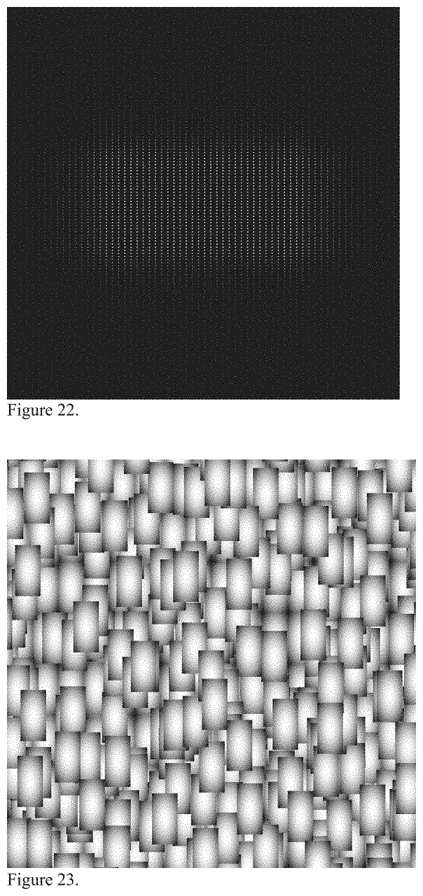

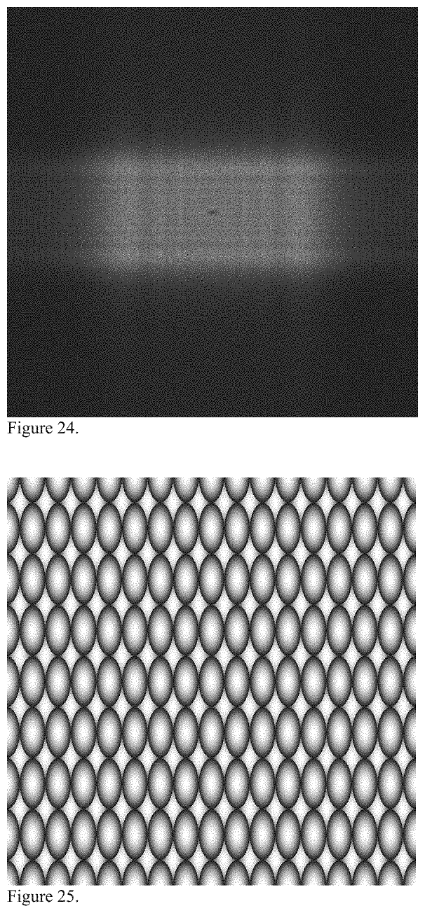

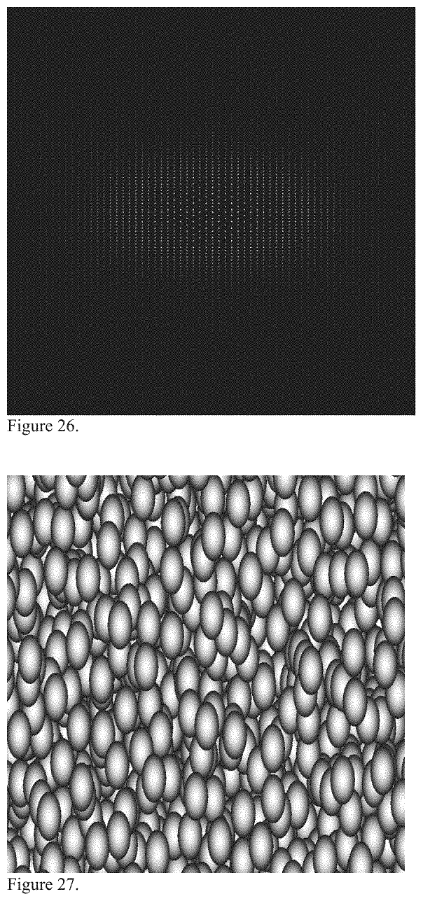

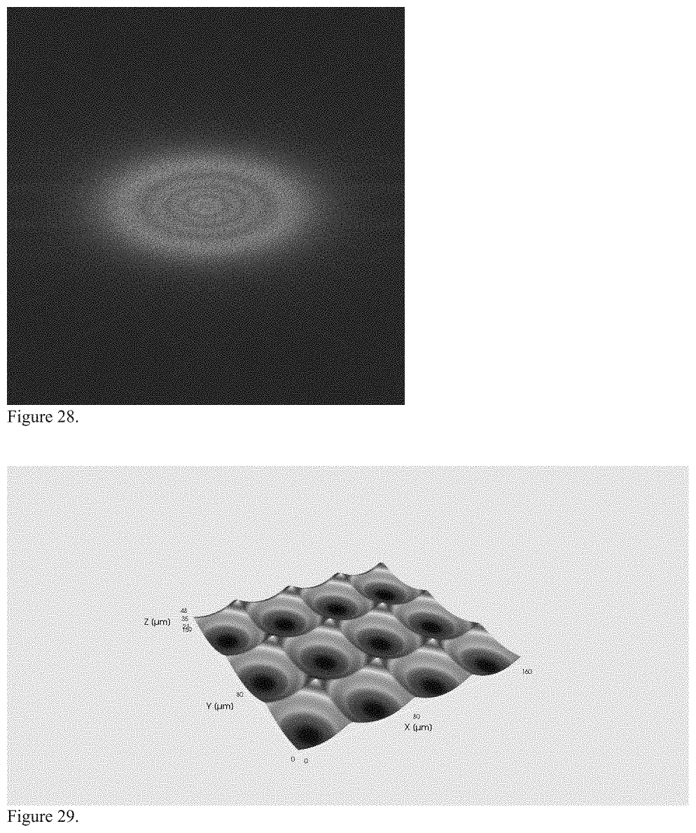

Different boundary shapes to the lenslets can be used to produce the different far field distribution profiles. The FIGS. 13 through 28 show simulations of the lens shapes and far field diffraction patterns. FIGS. 13 to 16 demonstrate the properties of a flat top diffuser intensity distribution of 20 degrees by 20 degrees (FTD 20×20) square. In FIG. 13, the lenslets are identical in size then shaped and arranged in a regularly spaced micro lens array (MLA). This arrangement produces the diffraction dot pattern seen in FIG. 14. The regularly spaced function produces a regularly spaced far field diffraction pattern, such as with diffraction gratings. In FIG. 15, the microstructure of randomly placed lenslets (RPL) are shown for the FTD 20×20. FIG. 16 shows the far field diffraction pattern of the FTD 20×20, where the dot pattern is eliminated. In a similar manner, a sampling of other FTD pattens are shown, where four figures are clustered in a set. Each set contains the regular MLA, the far field diffraction dot pattern resultant from the regular MLA, the RPL arrangement, and the far field diffraction pattern resulting from the RPL arrangement. The set of FTD 10×10 square intensity is shown in FIGS. 17 to 20. The set of FTD 20×10 rectangular intensity distribution is shown in FIGS. 21 to 24. The set of elliptical FTD 20×10 intensity distribution is shown in FIGS. 25 to 28.

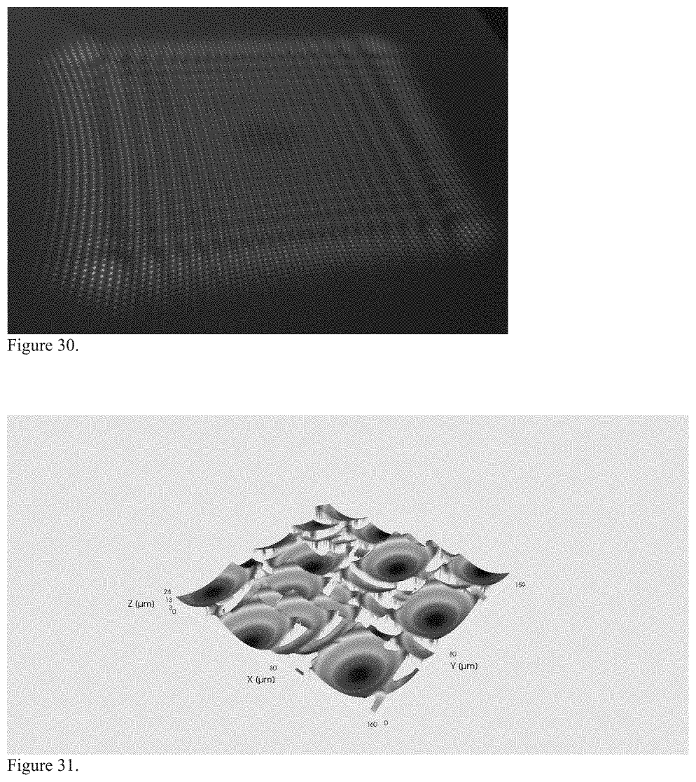

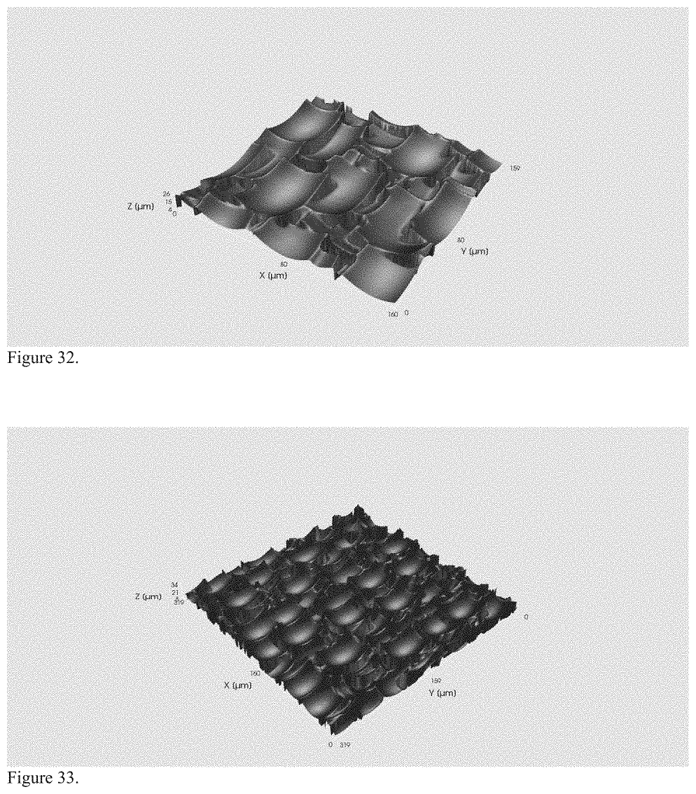

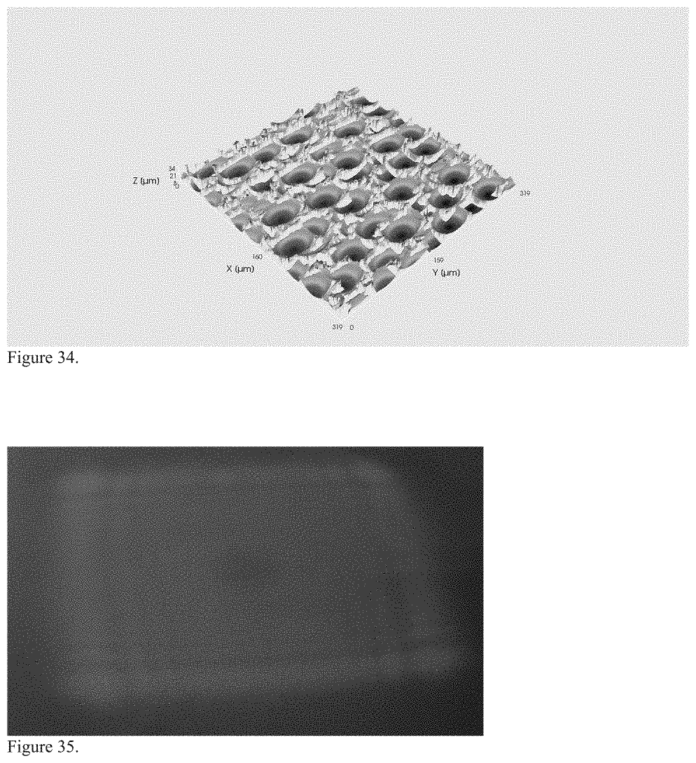

FIGS. 29 through 35 show measured results of the MLA and RPL designs. FIG. 29 is a Confocal (3D) microscope view of a regularly spaced MLA. Using a laser, FIG. 30 shows the far field diffraction pattern with the dots from the regularly spaced MLA. FIGS. 31 through 34 show the Confocal microscope views of the RPL type of microstructure. Using a laser, FIG. 35 shows the far field diffraction result of the RPL microstructure, which eliminated the dots in the pattern.

When introducing elements of the present disclosure or the preferred embodiment(s) thereof, the articles “a”, “an”, “the”, and “said” are intended to mean that there are one or more of the elements. The terms “comprising”, “including”, and “having” are intended to be inclusive and mean that there may be additional elements other than the listed elements.

What is claimed is:

1. An optical element comprising a micro-optic unit cell comprising one or more lenslets.

2. The optical element of claim 1 wherein the lenslets are randomly positioned.

3. The optical element of claim 1 wherein an intensity or irradiance profile of the micro-optic unit cell comprises a flat top, a gradient, or mixtures thereof.

4. The optical element of claim 1 further comprising coherent or incoherent light source.

5. The optical element of claim 1 wherein the boundary shape of the lenslet comprises a square, a rectangle, a circle, an ellipse, a hexagon, a star, a cross, a logo, a generic geometrical shape with enclosed boundary(ies) or mixtures thereof.

6. The optical element of claim 1 comprising a flat top.

7. The optical element of claim 1 wherein the lenslets are uniformly distributed within the micro-optic unit cell.

8. The optical element of claim 1 wherein a size of the micro-optic unit cell is based on lenslet size, beam size or source size, and/or shape of the optical element.

9. The optical element of claim 1 wherein the lenslets wrap around one or more edges of the micro-optic unit cell.

10. The optical element of claim 1 wherein the lenslet comprises a size of about 20-500 micrometers.

11. The optical element of claim 1 wherein the micro-optic unit cell comprises a size in the range of about 0.5-4 millimeters.

12. The optical element of claim 1 wherein the micro-lens array comprises a size of about 3 millimeters to about 6 inches having repeated micro-optic unit cells.

13. A method of making an optical element comprising a micro-optic unit cell comprising one or more lenslets comprising a first process of randomization based on statistical uniform distribution functions of a full area of the unit cell and a second process of randomization based on correcting a statistical uniform distribution function to in fill one or more deformed areas within the unit cell.

14. The method of claim 13 comprising a photolithography process to make a master or a part.

15. The method of claim 13 comprising use of a direct write laser machine to make a master or a part.

16. The method of claim 13 comprising a rubber master, a glass master, a metal master, or any solid material, which can be formed for replication.

17. The method of claim 13 comprising parts made of an optical material such as glass, metal, plastic, or any other solid material, which can be formed by replication.

18. The optical element of claim 1 wherein the boundary shapes are either all centered or all not centered about the optical axis of the lenslet in the unit cell.

19. The optical element of claim 1 where the lenslets have the same size and shape initially.

20. The optical element of claim 1 where the lenslets have the same orientation (not rotated) with respect to each other.
